(19) United States
(12) Patent Application Publication
(10) Pub. No.: US 2004/0089535 A1
(43) Pub. Date: May 13, 2004

(54) Process and apparatus for pulsed dc magnetron reactive sputtering of thin film coatings on large substrates using smaller sputter cathodes

(75) Inventors: Jesse Dennis Wolfe, Discovery Bay, CA (US); Steven Rex Bryan, Ripon, CA (US)

Correspondence Address: James S. Tak, Assistant Laboratory Counsel, Lawrence Livermore National Laboratory, P.O. Box 808, L-703, Livermore, CA, 94551, US

(73) Assignee: The Regents of the University of California.

(21) Appl. No.: 10/643,556

(22) Filed: Aug. 18, 2003

Related U.S. Application Data
(60) Provisional application No. 60/403,902, filed on Aug. 16, 2002.

(51) Int. Cl. C23C 14/32

(52) U.S. Cl. 204/192.12; 204/298.08; 204/298.07

(57) ABSTRACT

A pulsed dc reactive magnetron sputter deposition apparatus and process enables large substrates to be coated with one ore more sputter cathodes having a size smaller than the substrate. The reactive sputtering is provided over a long throw distance between the sputter cathode and the substrate, and approximating a long mean free path. The substrate to be coated due to the low pressures enabled by the use of pulsed DC magnetrons. The low pressures, e.g. less than 1 mTorr, allows for a long throw distance which approximates the long the mean free path. And a pulsed dc power source provides sufficient energies to emit sputtered target particles across the long throw distance to the substrate substantially without collision, to produce optical coating with optics grade qualities.

### CLAIM OF PRIORITY IN PROVISIONAL APPLICATION

This application claims priority in provisional application filed on Aug. 16, 2002, entitled “Process for Depositing Thin Film Coatings on Large Substrates Using Smaller Sputter Cathodes” Ser. No. 60/403902, by inventors Jesse D. Wolfe and Steven Rex Bryan, Jr.

The United States Government has rights in this invention pursuant to Contract No. W-7405-ENG-48 between the United States Department of Energy and the University of California for the operation of Lawrence Livermore National Laboratory.

### FIELD OF THE INVENTION

The present invention relates to sputter deposition processes, and more particularly to a pulsed dc magnetron reactive sputter deposition apparatus and process for coating large substrates, such as large optics, using sputter cathodes smaller than the substrate, low pressures, and long throw distances, whereby the mean free path enabled by the low pressures is greater than the long throw distance.

### BACKGROUND OF THE INVENTION

Various types of magnetron sputtering systems have been developed for depositing thin-film coatings of, for example, metals, oxides, and nitrides on substrates. Many if not most of these systems utilize a dc power source, and with the source-to-substrate distance, i.e. throw distance, often kept as short as possible in order for the emitted target atoms and molecules to be efficiently carried to the substrate by the sputtering energy with virtually no loss through collisions. For example, commercial dc magnetron sputtering of metals, oxides, and nitrides in most present systems takes place at a throw distance between 3-6 in. and gas pressures in the 1-5 mTorr range. The gas pressure in such dc magnetron sputtering systems is relatively high compared with the gas pressure in typical evaporation systems (˜10⁻⁶ mbar), with the mean free path of a sputtered particle therefore about three orders of magnitude less than a particle in an evaporation system.

In the semiconductor industry, however, dc magnetron sputter deposition techniques using long-throw distances (15-30 inches) and low pressures (<1 mTorr) have been developed to deposit metals and dielectrics into high aspect ratio trenches or vias on, for example, silicon or gallium arsenide wafers. Sputter depositions performed at pressures below 1 mTorr (0.13 Pa) are known to result in a virtually collision-free trajectory of the sputtered atoms from the target to the substrate. The low gas pressure allows a long mean free path between collisions and allows the sputtered particles to maintain high energy. If the throw distance from source to substrate is increased at these low pressures to the approximate length of the mean free path, the energy of the activated (ionized) gas and target atoms will be sufficient to reach the substrate. Thus the use of this geometry simulates electron beam evaporation as far as coating distribution is concerned.

In the case of optical applications, reactive sputtering techniques have been widely used for depositing thin film insulating/dielectric coatings on substrates. Reactive sputtering involves the introduction of a reactant gas to combine with the emitted/sputtered target particles to produce a compound deposited onto a substrate. A problem often seen with reactive sputtering, however, is the presence of target poisoning, arcing, and the consequent process instabilities which arise from the formation of insulating films on the target surface. Target poisoning and arcing occurs when an insulating compound (e.g. an oxide or nitride) is formed on the target surface, which leads to the accumulation of positive charge on the target surface during ion bombardment and consequently to arcing. It results in inhomogeneity and defects in the films and instabilities of the deposition process. In order to avoid and eliminate such target poisoning and arcing problems, pulsed DC power sources are often utilized in the magnetron reactive sputtering.

One example of a reactive sputtering apparatus/process utilizing low pressures and long throw distances is shown in U.S. Pat. No. 5,851,365 to Scobey. In Scobey a low pressure reactive magnetron sputtering apparatus is shown utilizing a dc powered reactive sputtering process with long throw distances (e.g. at least 16″) and low pressures (in the range of 5×10⁻⁵ Torr to 1.5×10⁻⁴ Torr). Inert gas such as argon is confined in the vicinity of the magnetrons, while a reactant gas, i.e. oxygen, is directed toward a substrate and away from the target using an ion gun. Use of the ion gun in Scobey operates to prevent buildup of an insulating compound layer on the target surface which may cause arcing. The use of a separate ion gun directing a reactant gas to the substrate, however, can add to the cost and complexity of the sputter deposition system. Additionally, Scobey describes the use of larger magnetrons (and cathodes) for coating larger substrates. However, one of the difficulties presented by magnetron sputter deposition on large parts is the insufficiency of space within a vacuum chamber. Usually, the cathodes or targets are required to be larger than the substrate to be coated in order to achieve uniform deposition as well as other superlative coating qualities. Since for most applications cathodes are generally larger than the substrates to be coated, this can be difficult to implement for larger substrates (e.g. >15 in.) due to cost and size of power supplies, sputter guns, etc.

There is a growing need for durable, stable, thin film optical coatings/multi-layers on various substrate materials, as well as thin-film deposition techniques to efficiently and cost-effectively produce the same. Such optical coatings/multi-layers for use in optical applications require high quality uniform deposition with very low levels of scatter and absorption. And this need exists in particular for applications requiring thin film optical coatings on large-scale substrates (e.g. >15 in.), such as for large telescopes (e.g. 10-40 meters), and the National Ignition Facility (NIF) at the Lawrence Livermore National Laboratory, in Livermore, Calif. The large-area coating requires high and stable deposition rates as well as reproducible and superlative optical layer properties. Thus, it would be advantageous to provide a sputter deposition system and method which takes advantage of the afore-mentioned advantages of long throw, low pressure sputtering, together with pulsed dc magnetron reactive sputtering methodology which enables the sputtering of large optics (>15 in. diameter) using cathodes smaller in size than the substrate, e.g. containable in a standard box coater. Such an apparatus and method will then also be capable of overcoming arcing without requiring reactant gas be kept distant from the target source.

### SUMMARY OF THE INVENTION

One aspect of the present invention includes a reactive magnetron sputter deposition apparatus for coating a substrate comprising: a vacuum chamber evacuated to a low pressure; at least one pulsed DC magnetron positioned within said vacuum chamber and having a target source for sputtered particles; means for positioning a substrate within said vacuum chamber a long throw distance away from and facing said at least one pulsed DC magnetron, said long throw distance being less than the mean free path of the sputtered particles due to said low pressure; and means for providing a reactant gas at said target source to form said sputtered particles, wherein the pulsed DC magnetron prevents target poisoning by the reactant gas at said target source.

Another aspect of the present invention includes a reactive magnetron sputter deposition process for coating large scale optics comprising: providing a vacuum chamber evacuated to a low pressure; providing at least one pulsed DC magnetron positioned within said vacuum chamber and having a target source for sputtered particles; providing means for positioning a substrate within said vacuum chamber a long throw distance away from and facing said at least one pulsed DC magnetron, said long throw distance being less than the mean free path of the sputtered particles due to said low pressure; and impinging said target source with a reactant gas to sputter said particles onto the substrate, wherein the pulsed DC magnetron prevents target poisoning by the reactant gas at said target source.

### BRIEF DESCRIPTION OF THE DRAWINGS

The accompanying drawings, which are incorporated into and form a part of the disclosure, are as follows:

FIG. 1 is a schematic diagram of a first exemplary embodiment of the present invention, having a single target source and only a reactant gas provided thereto.

FIG. 2 is a schematic view of a second exemplary embodiment of the present invention, having multiple target sources with both reactant and inert gases provided thereto.

### DETAILED DESCRIPTION

The present invention is generally directed to a reactive magnetron sputter deposition process and apparatus for coating optical thin-films on large-scale substrates. A pulsed DC magnetron reactive sputtering technique is utilized in combination with a long throw methodology at low pressure to deliver additional energy at the substrate. Preferably, the process and apparatus is utilized to coat optical thin films on large-scale substrates to produce large-scale optics. The system is ideal for producing optically coated substrates, such as mirrors, lens, prisms, light guides, etc. or other elements of an optical instrument or system because of the resulting uniformity, low absorption and scattering. Based on experiments associated with research conducted by Applicants at the Lawrence Livermore National Laboratory, this configuration has enabled, for example, the coating of large optics (>15 in diameter) in a standard box coater having dimensions of 4 ft.×4 ft.×5 ft. using smaller-diameter sputter cathodes.

The present invention utilizes the basic principles of magnetron sputter deposition, also known as physical sputtering or physical vapor deposition (PVD), which is a widely used coating technique for depositing thin film coatings on substrates. Magnetron sputtering is a relatively violent, atomic-scale process generally carried out in diode plasma systems known as magnetrons. On each magnetron, a target source (e.g. Si) is bombarded with ions of a sputtering gas (e.g. Ar). When struck by the sputtering gas atoms and ions, the sputtered target atoms/particles are energized as a result of the momentum transferred thereto and emitted toward a substrate, to produce a thin film of the sputtered target atoms/particles deposited on the substrate.

The configuration and operation of an exemplary basic magnetron is described as follows. A permanent magnet structure is located behind a target serving as a deposition source. And plasma confinement on the target surface is also achieved by locating a permanent magnet structure behind the target surface. The magnets are used to confine electrons in the plasma, resulting in higher plasma densities and consequently reducing the discharge impedance and results in a much higher current, lower-voltage discharge. The resulting magnetic field forms a closed-loop annular path acting as an electron trap that reshapes the trajectories of the secondary electrons ejected from target into a cycloidal path, greatly increasing the probability of ionization of the sputtering gas within the confinement zone. Inert gases, e.g. argon, are usually employed as the sputtering gas because they tend not to react with the target material or combine with any process gases and because they produce higher sputtering and deposition rates due to their high molecular weight. Positively charged argon ions from the plasma are accelerated toward the negatively biased target (cathode), resulting in material being sputtered from the target surface.

It is appreciated that the dynamics of the collision process depend strongly on the incident energy and mass of the bombarding particle. At relatively low energies, the incident particles do not have adequate energy to break atomic bonds of the surface atoms, and the bombardment process could result in simply desorbing a few lightly bound gas atoms, perhaps inducing a chemical reaction at the sample surface, or nothing at all. At relatively high incident energies, the bombarding particles travel deeply into the bulk of the substrate and may cause deep-level disruptions in the physical structure, but few if any surface atoms are released. And at the moderate energies, typically in the range from several hundred eV through several keV, the dislocations, and ejection or sputtering of atoms. It is further appreciated that the balanced magnetrons may be utilized having equal magnetic flux at each pole. Alternatively, unbalanced magnetrons may be utilized where the magnetic flux from one pole is greatly unequal to the other, to increase ion and electron bombardment of the growing film, at the significant expense of target utilization and insulating film growth on the target surface during reactive sputter deposition.

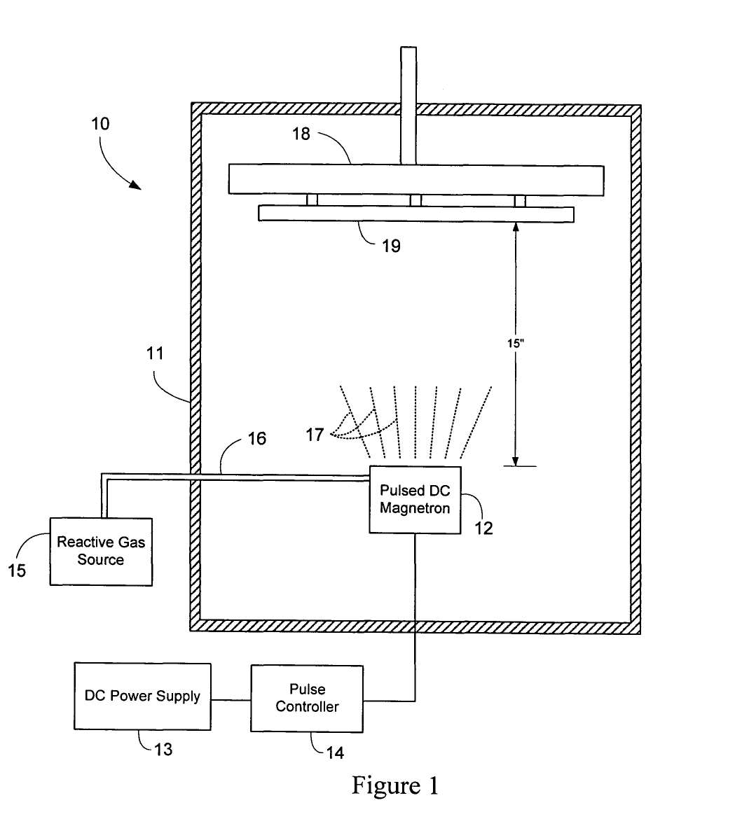

Turning to the drawings, FIG. 1 shows an exemplary embodiment of the pulsed dc magnetron reactive sputter deposition apparatus of the present invention, generally indicated at reference character 10. The apparatus 10 has a vacuum chamber 11 (generic shown) having a volume suitable for placing a large substrate 19 therewithin. While the vacuum chamber 11 is shown having a rectangular configuration, it is appreciated that other shapes and configurations may be utilized, such as a spherical design. Additionally, the vacuum chamber may have any suitable size dimensions as required by the application. For example, a 4 ft×4 ft×5 ft standard box coater may be utilized to accommodate one or more smaller-diameter (e.g. 6 in.) sputter cathodes as provided by the present invention. While not shown in the drawings, the vacuum chamber includes means for producing a vacuum in the chamber, such as by means of a vacuum pump. The pressure within the chamber is a low pressure suitable for supporting a long mean free path which is preferably greater than the long throw distance between the target source and a substrate. This is typically in the range of less than about 1 mTorr.

FIG. 1 also shows a single pulsed dc magnetron 12 positioned within the vacuum chamber 11 and having a target source (not shown) facing the substrate. A dc power supply 13 is connected to the magnetron 12, with the dc waveforms generated by the power supply pulsed by means of a suitable pulse controller 14 or a type known in the electrical arts. It is appreciated that pulsed dc magnetron sputtering is a technique based on the addition of a reverse-voltage bias pulse to the normal DC waveform. This bias pulse, provided by the pulse controller 14, when implemented at a frequency high enough to exploit the mobility differences between the ions and electrons in the plasma, accentuates the sputtering of dielectric films that accumulate on the target surface and effectively eliminates target poisoning and arcing. In particular, each magnetron target acts alternatively as an anode and a cathode during the pulse cycle, providing very long-term process stability at enhanced deposition rates. The magnetron 12 may operate in an asymmetric bipolar mode at the repetition frequency of pulses in the range from, for example, 20 to 350 kHz. The sputtering takes place from the target during a negative voltage pulsed, while discharging of the target surface takes place during a successive positive voltage pulse (typically 10% of the nominal “on” voltage.)

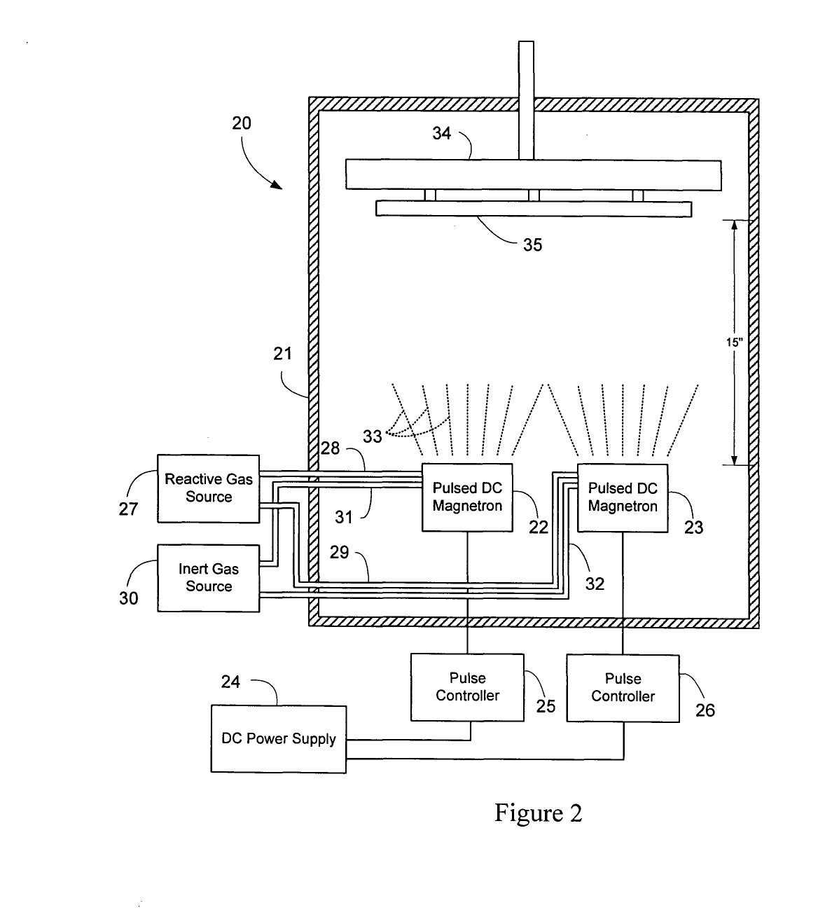

A reactant gas source 15 is also shown provided in FIG. 1 which supplies a reactant gas, such as oxygen or nitrogen gas, via a reactant gas supply line 16 to the target surface of the magnetron 12. The reactant gas may be used alone (as shown in FIG. 1) for bombarding the target source to emit sputtered target particles. Or in the alternative, the reactant gas may be introduced at the target source simultaneously with an inert gas, such as Argon (shown in FIG. 2), whereby a compound may be formed (e.g. an insulating dielectric such as an oxide or nitride). In any case, sputtered target particles 17 are sputtered in the direction of a relatively large substrate 19 shown mounted to a substrate holder assembly 18. And as shown in FIG. 1, the substrate 19 and holder assembly 18 are position such that the throw distance between the target surface and the substrate is about 15 inches or more, which is considered a long throw distance. Due to the low pressure within the vacuum chamber and the resulting long mean free path, the long throw distance is preferably chosen to approximate the mean free path (though slightly less) such that the momentum of each of the emitted target particles is sufficient to carry the particles to the substrate, without collision. Moreover, the long throw distance may be selectably determined based on a function of the width area of the substrate to be coated.

In this manner, the high frequency and pulsing components of the pulsed dc waveforms produces additional ionization of the pulsed plasma, resulting in a hotter (greater electron temperature), more chemically active plasma, which tends to improve the consistency of the film chemistry. This ionization enhancement, e.g. (1.5-2×), obviates the need for additional ion gun equipment which can substantially raise the costs involved in the sputtering apparatus and process as previously discussed. In particular, the present invention utilizes the pulsed DC power supplies having extra ionization capabilities and operates to introduce the reactive gas (e.g. O₂ or N₂) at the target surface, which obviates the need for extra ionization equipment such as large ion guns. Asymmetric bipolar pulsed DC enables existing PVD tools to produce the high quality, low defect dielectric films needed for next generation processes. Pulse frequency and duty cycle can be varied to optimize the process for a specific target material. This technique is especially appealing because it can be implemented on a single cathode. Asymmetric bipolar pulsed dc technology has proven to be particularly beneficial for the enhancement of the deposited films' qualities, film uniformity, and film characteristics, such as index of refraction (n) and absorption (k), due to changes in ion assisted deposition process caused by changes in plasma parameters. Examples include improvements in film density, hardness, stoichiometry and optical properties.

FIG. 2 shows a second embodiment of the present invention generally indicated at reference character 20, and having multiple magnetrons (two shown: 22, 23) positioned within a vacuum chamber 21. It is appreciated that the target source utilized for each of the magnetrons 22, 23 may be the same or different material types commonly known and used in the relevant art for sputter deposition. Additionally, when multiple magnetrons are utilized to produce the reactive sputtering, the long throw distance may be chosen as a function of the width area of the substrate to be coated. Moreover, the long throw distance may be determined as a function of the number of magnetrons utilized, for optimizing deposition. And similar to FIG. 1, the vacuum chamber 21 is also provided with a means for evacuating the vacuum chamber (not shown) to reach low-pressure levels less than 1 mTorr, and of a type known in the mechanical arts. A dc power supply 24 is provided and connected to each of magnetrons 22, 23 to provide power thereto. Pulse controllers 24 and 25 are provided which may operate independently for example to pulse the dc waveform to the magnetrons 22 and 23, respectively. Each of the magnetrons 22, 23 generally operate as described above to bombard the target surface with a suitable sputtering gas atom or ion, supplied directly to the target source.

With respect to the sputtering gas supplied to the magnetrons, the second embodiment of the present invention shows the provision of both an inert gas and a reactant gas at the target surface. In particular a reactive gas source 27 is provided for supplying a reactive gas, e.g. oxygen or nitrogen, to one or both of the magnetrons 22, 23, and indicated by reactant gas supply lines 28 and 29, respectively. Additionally, an inert gas source 30 is also provided to supply an inert gas, such as argon, to each of the magnetrons 22, 23, and as indicated by inert gas supply lines 31 and 32, respectively. Where both gases are provided to produce, for example, an oxide compound in a reactive sputtering process, the inert gas may be alone employed (for its greater mass) to effect ion bombardment of the target surface. In any case, a reaction between the reactant gas, e.g. oxygen, and the emitted target particle, e.g. silicon, produces a compound, e.g. SiO₂, which is deposited on the substrate. This obviates the need for additional/costly equipment for directing a reactant gas away from the target cathode (to avoid poisoning). It can be appreciated that each additional target source serves to reduce the partial pressure of the reactant gas of every target source without a corresponding reduction in the impingement ration due to the increase in total ionization provided by the additional target source. And each additional target source additionally reduces the partial pressure of the inert gas for every target source to maintain the low pressure within the vacuum chamber.

Due to the long throw distance and low pressures of the present invention, multiple magnetrons may be utilized with each having a smaller width and/or area than the substrate to be coated. This allows for smaller footprints and configurations, as well as allowing the use of standard size box coaters, such as the 4 ft×4 ft by 5 ft box coater previously discussed. In a preferred embodiment, the target source is smaller than the width/area of the substrate to be coated by at least a factor of three. As an illustrative approximation, a 4 meter mirror would be coated using, for example, a single cathode only 1.33 meters in length, or alternatively multiple circular cathodes having 6 inch diameters. This would provide a tremendous savings in cost for sputter guns and size of power supplies, etc. By operation of the apparatus and process of the present invention, such thin film coatings may be deposited as, for example, durable silver mirrors, high damage threshold laser coatings, anti-reflective/high reflective all dielectric films, etc. As an illustrative example, Applicants have been successful in employing the process of the present invention to sputter coat a 22 inch diameter optic for the Keck Telescope in Hawaii with a new Wide-Band Durable Silver Mirror.

While particular operational sequences, materials, temperatures, parameters, and particular embodiments have been described and or illustrated, such are not intended to be limiting. Modifications and changes may become apparent to those skilled in the art, and it is intended that the invention be limited only by the scope of the appended claims.

I claim:

1. A reactive magnetron sputter deposition apparatus for coating a substrate comprising:
a vacuum chamber evacuated to a low pressure;
at least one pulsed DC magnetron positioned within said vacuum chamber and having a target source for sputtered particles;
means for positioning a substrate within said vacuum chamber a long throw distance away from and facing said at least one pulsed DC magnetron; and
means for providing a reactant gas at said target source to form said sputtered particles, wherein operation of the pulsed DC magnetron prevents target poisoning by the reactant gas at said target source.

2. The apparatus of claim 1,
wherein said means for providing a reactant gas additionally provides an inert gas at said target source to form said sputtered particles.

3. The apparatus of claim 1,
wherein said low pressure is below about 1 mTorr.

4. The apparatus of claim 1,
wherein said long throw distance is greater than about 15 inches.

5. The apparatus of claim 1,
wherein said target source is smaller than the width/area of the substrate to be coated.

6. The apparatus of claim 5,
wherein said target source is smaller than the width/area of the substrate to be coated by at least a factor of three.

7. The apparatus of claim 1,
wherein said long throw distance is a function of the width/area of the substrate to be coated.

8. The apparatus of claim 7,
wherein said long throw distance is additionally a function of the number of said pulsed DC magnetrons/target sources utilized.

9. The apparatus of claim 1,
further comprising a plurality of pulsed DC magnetrons having a corresponding plurality of target sources.

10. The apparatus of claim 9,
wherein each additional target source reduces the partial pressure of the reactant gas of every target source without a corresponding reduction in the impingement ratio due to the increase in total ionization provided thereby.

11. The apparatus of claim 9,
wherein said means for providing a reactant gas additionally provides an inert gas at each target source to form said sputtered particles, and each additional target source reduces the partial pressure of at least the reactant gas for every target source without a corresponding reduction in the impingement ratio due to the increase in total ionization provided thereby.

12. The apparatus of claim 11,
wherein each additional target source additionally reduces the partial pressure of the inert gas for every target source to maintain said low pressure within said vacuum chamber.

13. A reactive magnetron sputter deposition process for coating large scale optics comprising:
providing a vacuum chamber evacuated to a low pressure;
providing at least one pulsed DC magnetron positioned within said vacuum chamber and having a target source for sputtered particles;
providing means for positioning a substrate within said vacuum chamber a long throw distance away from and facing said at least one pulsed DC magnetron; and
impinging said target source with a reactant gas to sputter said particles onto the substrate, wherein operation of the pulsed DC magnetron prevents target poisoning by the reactant gas at said target source.

14. The process of claim 13,
further comprising impinging said target source with an inert gas at said target source to sputter said particles onto the substrate.

15. The process of claim 13,
wherein said low pressure is below about 1 mTorr.

16. The process of claim 13,
wherein said long throw distance is greater than about 15 inches.

17. The process of claim 13,
wherein said target source is smaller than the width/area of the substrate to be coated.

18. The process of claim 17,
wherein said target source is smaller than the width/area of the substrate to be coated by at least a factor of three.

19. The process of claim 13,
wherein said long throw distance is a function of the width/area of the substrate to be coated.

20. The process of claim 19,
wherein said long throw distance is additionally a function of the number of said pulsed DC magnetrons/target sources utilized.

21. The process of claim 13,
further comprising a plurality of pulsed DC magnetrons having a corresponding plurality of target sources.

22. The process of claim 21,
wherein each additional target source reduces the partial pressure of the reactant gas of every target source without a corresponding reduction in the impingement ratio due to the increase in total ionization provided thereby.

23. The process of claim 21,
wherein said means for providing a reactant gas additionally provides an inert gas at each target source to form said sputtered particles, and each additional target source reduces the partial pressure of at least the reactant gas for every target source without a corresponding reduction in the impingement ratio due to the increase in total ionization provided thereby.

24. The process of claim 23,
wherein each additional target source additionally reduces the partial pressure of the inert gas for every target source to maintain said low pressure within said vacuum chamber.
